(19) United States
(12) Patent Application Publication
(10) Pub. No.: US 2024/0186119 A1
(43) Pub. Date: Jun. 6, 2024

(54) SUBSTRATE PROCESSING APPARATUS, PLASMA MEASUREMENT METHOD, AND PLASMA REGULATION METHOD

(71) Applicant: Tokyo Electron Limited, Tokyo (JP)

(72) Inventor: Makoto ISHITSUBO, Nirasaki City (JP)

(21) Appl. No.: 18/524,015

(22) Filed: Nov. 30, 2023

(30) Foreign Application Priority Data
Dec. 6, 2022 (JP) 2022-195125

(51) Int. Cl. H01J 37/32; H01L 21/3065

(52) U.S. Cl. CPC H01J 37/32449; H01J 37/32091; H01J 37/32174; H01L 21/3065

(57) ABSTRACT

A substrate processing apparatus includes: a processing container having a processing space; a gas supply mechanism for supplying a reaction gas to the processing space; a shower head which is arranged in the processing space and discharges the reaction gas into the processing space; a stage which is arranged to face the shower head in the processing space, the stage and the shower head being configured to constitute parallel flat-plate electrodes; a first radio-frequency power supply which is connected to either the shower head or the stage and supplies first radio-frequency power to generate a plasma of the reaction gas between the electrodes; a second radio-frequency power supply for supplying second radio-frequency power to the plasma; and an analyzer for acquiring a mixed wave of the first and second radio-frequency powers and analyzing a state of the plasma based on a result of measuring a power level of the mixed wave.

### CROSS-REFERENCE TO RELATED APPLICATION

This application is based upon and claims the benefit of priority from Japanese Patent Application No. 2022-195125, filed on Dec. 6, 2022, the entire contents of which are incorporated herein by reference.

### TECHNICAL FIELD

The present disclosure relates to a substrate processing apparatus, a plasma measurement method, and a plasma regulation method.

### BACKGROUND

In processing such as film formation and etching in the manufacturing process of semiconductor devices or flat panel display (FPDs), plasma of a processing gas is sometimes used to obtain highly-reactive active species at a relatively low temperature. In a plasma processing apparatus, it may be necessary to measure a state of a plasma such as the density and temperature in order to control a processing on a substrate. Patent Document 1 discloses a technique for measuring a plasma absorption frequency and obtaining the density of electrons, which is an example of the state of the plasma, using a probe part arranged inside a chamber.

### PRIOR ART DOCUMENT

### Patent Document

Patent Document 1: Japanese Laid-Open Patent Publication No. 2004-103264

### SUMMARY

According to one embodiment of the present disclosure, a substrate processing apparatus includes: a processing container having a processing space in which a substrate is processed; a gas supply mechanism configured to supply a reaction gas to the processing space; a metal-made shower head arranged in the processing space and connected to the gas supply mechanism, the metal-made shower head being configured to discharge the reaction gas supplied from the gas supply mechanism into the processing space; a metal-made stage arranged to face the metal-made shower head in the processing space, the metal-made stage being configured to place the substrate on the metal-made stage, and the metal-made stage and the metal-made shower head being configured to constitute parallel flat-plate electrodes; a first radio-frequency power supply connected to either the metal-made shower head or the metal-made stage and configured to supply first radio-frequency power to generate a plasma of the reaction gas between the parallel flat-plate electrodes; a second radio-frequency power supply configured to supply second radio-frequency power to the plasma, the second radio-frequency power having a frequency different from a frequency of the first radio-frequency power; and an analyzer configured to acquire a mixed wave of the first radio-frequency power and the second radio-frequency power, which is obtained by the generation of the plasma, and to analyze a state of the plasma based on a result obtained by measuring a power level of the mixed wave.

### BRIEF DESCRIPTION OF DRAWINGS

The accompanying drawings, which are incorporated in and constitute a part of the specification, illustrate embodiments of the present disclosure, and together with the general description given above and the detailed description of the embodiments given below, serve to explain the principles of the present disclosure.

FIG. 1 is a longitudinal cross-sectional view illustrating a film forming apparatus according to a first embodiment of the present disclosure.

FIG. 2 is a diagram illustrating an equivalent circuit of a circuit including a first radio-frequency power supply and a second radio-frequency power supply of the first embodiment.

FIG. 3 is a graph illustrating a relationship between current passing through a diode and a voltage.

FIG. 4 is a graph illustrating measurement results of a power level.

FIG. 5 is a longitudinal cross-sectional view illustrating a film forming apparatus according to a second embodiment.

FIG. 6 is a longitudinal cross-sectional view illustrating a film forming apparatus according to a third embodiment.

FIG. 7 is a graph illustrating results of a preliminary test in Example 1.

FIG. 8 is a graph illustrating results of a preliminary test in Comparative Example.

FIG. 9 is a graph illustrating results of a simulation in Example 2.

FIG. 10 is a graph illustrating results of a simulation in Example 3.

FIG. 11 is a graph illustrating results of a simulation in Example 4.

### DETAILED DESCRIPTION

Reference will now be made in detail to various embodiments, examples of which are illustrated in the accompanying drawings. In the following detailed description, numerous specific details are set forth in order to provide a thorough understanding of the present disclosure. However, it will be apparent to one of ordinary skill in the art that the present disclosure may be practiced without these specific details. In other instances, well-known methods, procedures, systems, and components have not been described in detail so as not to unnecessarily obscure aspects of the various embodiments.

### First Embodiment

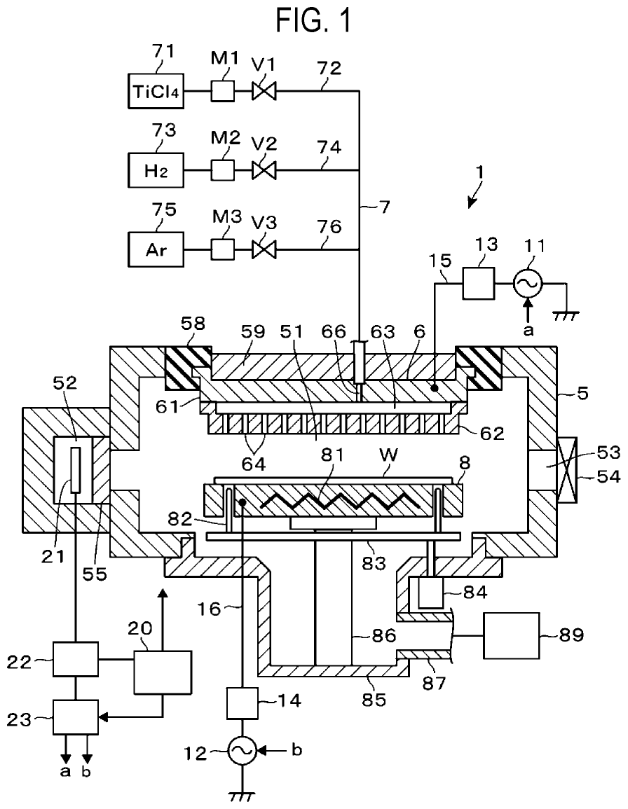

Hereinafter, as a first embodiment of a substrate processing apparatus according to the present disclosure, a film forming apparatus 1 that forms a titanium (Ti) thin film on a substrate such as a semiconductor wafer W (hereinafter referred to as substrate W) by a chemical vapor deposition (CVD) method will be described with reference to FIG. 1. The film forming apparatus 1 is configured to perform a film formation processing on the substrate W by forming a capacitively coupled plasma from a processing gas using parallel flat-plate electrodes.

FIG. 1 is a longitudinal cross-sectional view illustrating the film forming apparatus 1 according to this example. The film forming apparatus 1 includes a metal-made processing container 5, a shower head 6 provided at a top portion of the processing container 5, and a gas supply mechanism 7 that supplies processing gases into the processing container 5 via the shower head 6. The processing container 5 includes a processing space 51 in which the substrate W is processed and an antenna space 52 provided to be adjacent to the processing space 51. The processing container 5 is configured to maintain the processing space 51 having a substantially cylindrical shape in an airtight manner.

The processing container 5 is provided at a sidewall thereof with a loading/unloading port 53 for loading and unloading the substrate W, and a gate valve 54 for opening and closing the loading/unloading port 53. A metal-made stage 8 for horizontally placing the substrate W thereon is provided inside the processing container 5. The stage 8 is arranged to face the shower head 6. A substrate heater 81 is embedded in the stage 8. The substrate heater 81 heats the substrate W to a preset temperature upon receiving power supplied from a power supply (not illustrated).

The stage 8 is provided with three (only two are illustrated) substrate supporting pins 82 for supporting and moving the substrate W up and down in such a way that the substrate supporting pins 82 are able to protrude and retract relative to a surface of the stage 8. These substrate supporting pins 82 are fixed to a supporting plate 83. The substrate supporting pins 82 are raised and lowered by a drive mechanism 84 such as an air cylinder via the supporting plate 83.

A stage holder 85 having a downwardly protruding cup-shape is attached to an opening at a bottom center of the processing container 5 via a seal ring (not illustrated). The stage 8 may be supported by a cylindrical post 86 which is attached to the stage holder 85. The processing container 5 and the stage holder 85 include a heating mechanism (not illustrated). The processing container 5 and the stage holder 85 are heated to a preset temperature when power is supplied to the heating mechanism from a power supply (not illustrated).

An exhaust pipe 87 is connected to a bottom sidewall of the stage holder 85, and an exhaust device 89 is connected to the exhaust pipe 87 and is configured to exhaust the processing space 51. By operating the exhaust device 89, the processing space 51 of the processing container 5 may be depressurized to a preset vacuum level.

A transparent window 55 is formed in the processing container 5 and serves as a partition between the processing space 51 and the antenna space 52. The transparent window 55 is arranged to span both the processing space 51 and the antenna space 52. In other words, the antenna space 52 is provided to be adjacent to the processing space 51 via the transparent window 55. The transparent window 55 is made of, for example, a resin, and is configured to transmit electromagnetic waves propagating in the processing space 51 to introduce them into the antenna space 52 while maintaining an airtight seal between the processing space 51 and the antenna space 52.

The shower head 6 is made of a metal, and is arranged to face the stage 8 in the processing space 51. The shower head 6 and the stage 8 constitute parallel flat-plate electrodes. These parallel flat-plate electrodes are capacitively coupled upon the supply of radio-frequency power as described later to generate a plasma therebetween. The shower head 6 is heated by a heater or the like and is attached to the processing container 5 via an insulating member 58 having electric insulation and thermal insulation properties. Further, the top of the shower head 6 is covered with an upper lid 59.

The shower head 6 includes a base plate 61 and a shower plate 62. The shower plate 62 has a raised periphery in contact with a lower surface of the base plate 61. A gas diffusion space 63 for diffusing processing gases is defined between the shower plate 62 and the base plate 61. A plurality of gas discharge holes 64 are formed in the shower plate 62, while a gas introduction hole 66 is formed near the center of the base plate 61 and the upper lid 59.

The gas supply mechanism 7 is connected to the gas introduction hole 66 for supplying processing gases such as a raw material gas and a reaction gas. The gas supply mechanism 7 includes a TiCl₄ gas supplier configured to supply a titanium tetrachloride (TiCl₄) gas, which is a Ti compound, into the processing container 5. The TiCl₄ gas supplier includes a TiCl₄ gas source 71 and a gas supply path 72. The gas supply path 72 is provided with a flow rate adjuster M1 and a valve V1 in order from the upstream side. The TiCl₄ gas serves as a raw material gas, which is a film forming material.

Further, the gas supply mechanism 7 includes a H₂ gas supplier configured to supply a hydrogen (H₂) gas, which is a reducing gas, and an Ar gas supplier configured to supply an argon (Ar) gas for plasma generation and purging. The H₂ gas supplier includes a H₂ gas source 73 and a gas supply path 74. The gas supply path 74 is provided with a flow rate adjuster M2 and a valve V2 in order from the upstream side.

The Ar gas supplier includes an Ar gas source 75 and a gas supply path 76. The gas supply path 76 is provided with a flow rate adjuster M3 and a valve V3 in order from the upstream side. The H₂ gas and the Ar gas serve as reaction gases for reacting with molecules of the raw material gas. With the above configuration, these processing gases flow into the gas diffusion space 63 and are discharged into the processing space 51 via the gas discharge holes 64 of the shower plate 62. For example, during a film formation processing, the gas supply mechanism 7 continuously supplies the Ar gas into the processing space 51, and alternately supplies the TiCl₄ gas, which is a raw material gas, and the H₂ gas, which is a reaction gas. By supplying power to the parallel flat-plate electrodes during the supply of the Ar gas and the H₂ gas, which are reaction gases, the H₂ gas is plasmarized.

Next, a first radio-frequency power supply 11 and a second radio-frequency power supply 12, which are connected to the parallel flat-plate electrodes constituted with the shower head 6 and the stage 8, will be described. The first radio-frequency power supply 11 has one end connected to the base plate 61 of the shower head 6 via a first matcher 13, and the other end thereof is grounded. The first radio-frequency power supply 11 supplies first radio-frequency power to the shower head 6 to generate plasma between the parallel flat-plate electrodes. A case where power, with a frequency of 1 megahertz (MHz), is supplied at the level of tens to hundreds of kilowatts (KW) as the first radio-frequency power, may be exemplified.

The second radio-frequency power supply 12 has one end connected to the stage 8 via a second matcher 14, and the other end thereof is grounded. The second radio-frequency power supply 12 supplies second radio-frequency power to the stage 8 for plasma biasing. The second radio-frequency power supply 12 has a frequency different from that of the first radio-frequency power and supplies lower power than the first radio-frequency power. A case where power, with a frequency of 2 megahertz (MHz), is supplied at the level of a few watts to tends of watts as the second radio-frequency power, may be exemplified. The first matcher 13 and the second matcher 14 are configured to output the first radio-frequency power and the second radio-frequency power, respectively, which match the impedance of a plasma in the processing space 51 on the output side. Hereinafter, a wiring that connects the shower head 6, the first radio-frequency power supply 11, and the first matcher 13 is referred to as a first transmission path 15, and a wiring that connects the stage 8, the second radio-frequency power supply 12 and the second matcher 14 is referred to as a second transmission path 16.

Next, a configuration related to plasma control will be described. The film forming apparatus 1 includes: an antenna 21 arranged in the antenna space 52; an analyzer 22 equipped with a detector that outputs electrical signals indicating the frequency and power level of electromagnetic waves received by, for example, the antenna 21, and a computer; a power adjuster 23; and a controller 20. The antenna 21 is formed of a conductor having a shape and length to achieve preset antenna characteristics and is configured to receive electromagnetic waves (mixed waves to be described later) emitted from the plasma and transmitted through the transparent window 55.

The controller 20 includes a program, a memory, and a data processor including a CPU. The program incorporates commands for sending control signals from the controller 20 to each part of the film forming apparatus 1 and proceeding each operation (film forming operation) related to a film formation processing. The program is stored in a non-transitory computer-readable storage medium such as a flexible disk, compact disk, hard disk, magneto-optical (MO) disk, or non-volatile memory, and is installed in the controller 20. The controller 20 controls and operates each component in the film forming apparatus 1 based on an operator input and a preset program. In particular, the controller 20 operates the analyzer 22 and the power adjuster 23 in order to control a plasma appropriately for the film forming operation.

The analyzer 22 is connected to the antenna 21 and is configured to measure the frequency and power level of electromagnetic waves based on the electromagnetic waves received via the antenna 21. The analyzer 22 is configured to measure the power level for each frequency of the acquired electromagnetic waves, and specifically includes a spectrum analyzer using the Fast Fourier transform (FFT). The power level indicates a power amplitude of the received electromagnetic waves and is specifically expressed in decibels (dB) with a reference value of 1 milliwatt (mW). Further, the analyzer 22 includes a component to analyze a state of the plasma based on results obtained by measuring the power level of the acquired electromagnetic waves.

The power adjuster 23 is connected at the input side thereof to the analyzer 22 and is connected at the output side thereof to the first radio-frequency power supply 11 and the second radio-frequency power supply 12. The power adjuster 23 adjusts the power supplied to the first radio-frequency power supply 11 according to the state of the plasma analyzed by the analyzer 22.

Next, actions of a plasma-based film formation processing performed by the film forming apparatus 1 according to the present embodiment will be described. When the first radio-frequency power is supplied to the shower head 6 from the first radio-frequency power supply 11, an electric field is created between the parallel flat-plate electrodes by capacitive-coupling of the parallel flat-plate electrodes. By this electric field, molecules of the supplied H₂ gas are ionized (plasmaized) into electrons and active species that promote the film formation processing. The emitted electrons then collide with other molecules, leading to a chain reaction of plasmaization. A large number of active species are accelerated by the electric field toward the substrate W placed on the stage 8 and collide with a processing target surface of the substrate W to facilitate reactions.

Then, when the second radio-frequency power is supplied to the stage 8 from the second radio-frequency power supply 12 simultaneously with the supply of the first radio-frequency power, a bias is applied to the plasma so that a degree of collision of the plasma with the substrate W is regulated. Further, in the plasma-based film formation processing, a degree of the film formation processing is adjusted by managing the plasma state, mainly the plasma temperature and density.

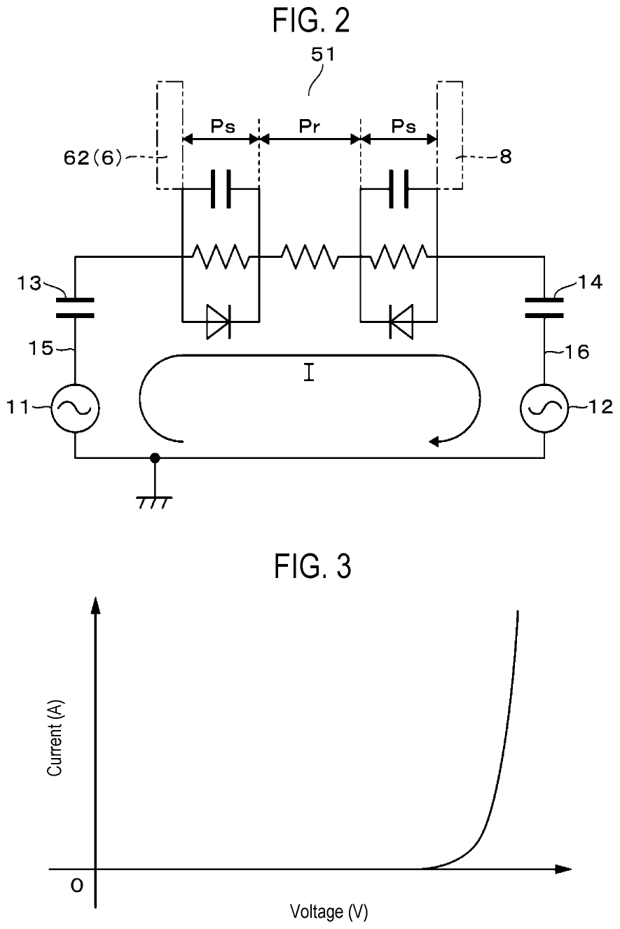

As illustrated in FIG. 2, a plasma space, which is created between the parallel flat-plate electrodes upon the supply of power as described above, includes two sheath regions Ps, which are boundary regions between the plasma space and each parallel flat-plate electrode, and a plasma region Pr between the two sheath regions Ps. Each sheath region Ps is known to function as a diode with rectifying and nonlinear characteristics. Therefore, an equivalent circuit of a circuit including the first radio-frequency power supply 11, the second radio-frequency power supply 12, and the two parallel flat-plate electrodes with the plasma space therebetween is represented as including diodes.

This equivalent circuit includes a plasma space circuit corresponding to the plasma space. In this plasma space circuit, respective circuits corresponding to the two sheath regions Ps and the plasma region Pr are connected in series. A plasma region circuit corresponding to the plasma region Pr includes a resistor. In each of two sheath region circuits corresponding to the sheath regions Ps, a condenser, a resistor, and a diode for the flow of current toward the plasma region circuit are connected in parallel.

The first radio-frequency power supply 11 and the first matcher 13 are connected in series. The second radio-frequency power supply 12 and the second matcher 14 are connected in series in the reverse order to the first radio-frequency power supply 11 and the first matcher 13. Further, the first radio-frequency power supply 11 and the first matcher 13 are connected in series with the second radio-frequency power supply 12 and the second matcher 14 with an equivalent circuit of the plasma space therebetween. In this equivalent circuit, the first radio-frequency power supplied from the first radio-frequency power supply 11 and the second radio-frequency power supplied from the second radio-frequency power supply flow through the plasma space circuit.

When two different frequencies of the first radio-frequency power and the second radio-frequency power pass through the sheath regions Ps with nonlinear characteristics, the first radio-frequency power and the second radio-frequency power are mixed to generate mixed waves. For each frequency of the first radio-frequency power and the second radio-frequency power, the mixed waves include a sum mixed wave with the sum of the frequencies, a difference mixed wave with a difference between the frequencies, and harmonics of the sum mixed waves and the difference mixed waves. These mixed waves become distorted waves with numerous frequencies.

The mixed waves are emitted from the plasma and propagate within the processing space 51 illustrated in FIG. 1. For example, the mixed waves pass through the transparent window 55 and are introduced into the antenna space 52. Further, the mixed waves propagating within the processing space 51 also propagate through the first transmission path 15 and the second transmission path 16 from the parallel flat-plate electrodes.

However, the diode equivalent to the sheath region exhibits a nonlinear relationship between current and voltage, as illustrated in FIG. 3. This diode characteristic may be observed from mixed waves generated by this diode, particularly the sum mixed wave, the difference mixed wave, and the harmonics thereof. Hereinafter, these “sum mixed wave”, “difference mixed wave”, and “the harmonics thereof” are collectively referred to as “sum and difference mixed waves”. The current passing through this diode is approximated by the equation Ir(exp(qV/kT)), where Ir is the reverse saturation current, q is the charge of electrons, V is the forward voltage, k is the Boltzmann constant, and T is the absolute temperature between the parallel flat-plate electrodes. To ensure that the sum and difference mixed waves having passed through the sheath region Ps satisfy this approximate equation, the temperature T in the approximate equation is replaced by the plasma temperature.

Further, the current flowing through the sheath region Ps is expressed by the sum of ion current Ji and electron current Je, but may be approximated by the electron current Je since the electron current Je is typically much greater than the ion current Ji. This electron current Je in the sheath region Ps is expressed by eN(KT/2πm)^{1/2}exp(−eϕ/kT) using the plasma density N, plasma temperature T, the mass of ions m, and the surface wall potential ϕ of the parallel flat-plate electrodes.

The equation for the current flowing through the diode and the equation for the current flowing through the sheath region Ps are equivalent, and therefore, respective proportional terms and exponential terms correspond to each other. From the comparison of the proportional terms, it can be said that the reverse saturation current Ir in the diode current equation has the plasma density N and plasma temperature T as parameters. Both exponents of the exponential terms in the diode and sheath current equations have the plasma temperature T as a parameter. Therefore, the current (power) of the mixed waves varies due to changes in the plasma density N and the plasma temperature T. Accordingly, the film forming apparatus 1 can analyze the plasma state such as the plasma density N and the plasma temperature T by observing the current or power of the sum and difference mixed waves.

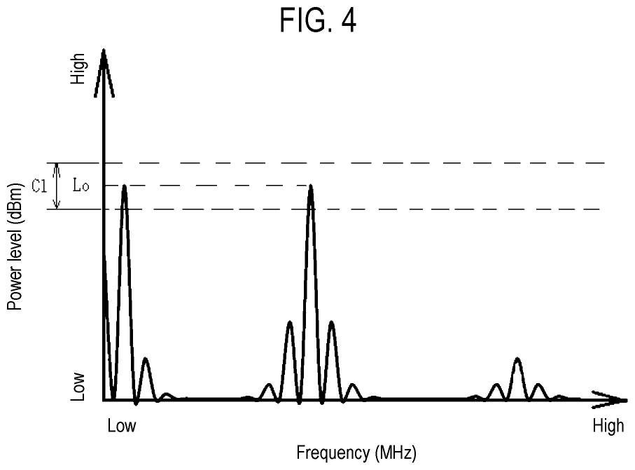

The analyzer 22 measures a power level of the mixed waves, specifically the sum and difference mixed waves, based on the mixed waves received by the antenna 21, as illustrated in FIG. 4. The analyzer 22 analyzes the plasma state based on the results of measuring the power level of the sum and difference mixed waves. The analysis of the plasma state is performed, for example, by measuring an initial power level L0 in a preset initial plasma state, and then continuously measuring the power level to observe a temporal change in the power level. For example, as illustrated in FIG. 4, a control range c1 is preset for a variation relative to the initial power level L0. Then, as will be described later, when the measured power level L deviates from this control range c1, it can be determined that, for example, the plasma temperature or plasma density has deviated from the acceptable state.

The control range c1 is preset as a control range of the power level corresponding to the control range of the plasma state that is acceptable from the viewpoint of the film formation processing relative to the plasma state at a reference power level such as the initial power level L0. This control range c1 may be acquired, for example, as a correspondence relationship between the power level and the plasma state, which are measured in advance using a spectrum analyzer and a Langmuir probe.

In the observation of a change in the power level, when the power level converges within the control range c1 of the initial power level L0, the analyzer 22 may determine that the plasma state is within the acceptable range from the viewpoint of the film formation processing relative to the initial plasma state. Then, the analyzer 22 may determine that the plasma state is a continuously possible state (sustainably maintainable state) for the film formation processing.

On the other hand, when the power level changes beyond the control range c1, the analysis result of the analyzer 22 is that the plasma state has changed beyond the acceptable range from the viewpoint of the film formation processing relative to the initial plasma state. Then, the analyzer 22 may determine that the plasma state has changed to a state where it may not be able to perform the same processing as the film formation processing in the initial plasma state (unsustainable state).

When the sustainably maintainable state is determined by the analysis result of the analyzer 22, the power adjuster 23 maintains the current situation. On the other hand, the unsustainable state is determined by the analysis result of the analyzer 22, the power adjuster 23 adjusts, for example, the first radio-frequency power by increasing or decreasing it to bring the power level closer to the initial power value L0, which is a target value. Thus, when the power level is adjusted to fall within the control range c1, the analyzer 22 continues to observe a change in the power level as described above.

When the adjustment of the power level is insufficient in the above method, the power adjuster 23 may stop the supply of the first radio-frequency power, and the controller 20 may temporarily stop the film forming operation of the film forming apparatus 1. In this case, the controller 20 operates the gas supply mechanism 7 and the power adjuster 23 again to return to the initial plasma state, the analyzer 22 measures the power level to analyze the plasma state, and the power adjuster 23 adjusts the first radio-frequency power.

As described above, the film forming apparatus 1 applies the first radio-frequency power and the second radio-frequency power with different frequencies to the parallel flat-plate electrodes, thereby generating plasma between the parallel flat-plate electrodes, as well as mixed waves. The analyzer 22 acquires the mixed waves via the antenna and analyzes the plasma state based on the measurement results of at least one power level of the mixed waves. Therefore, the film forming apparatus 1 can determine the plasma state from the mixed waves propagating from the processing space 51 to the antenna space 52.

Further, the analyzer 22 may determine the plasma state based on the control range c1, which is a correspondence relationship between the previously-acquired power level and plasma state. Further, the power adjuster 23 may adjust the power supplied to the first radio-frequency power supply 11 (by increasing or decreasing the power, or by stopping the supply of the power or re-supplying the power) based on the plasma state analyzed from the power level, thereby easily adjusting the plasma state.

Further, the film forming apparatus 1 of the present embodiment may analyze plasma state values corresponding to a power level of sum and difference mixed waves to be measured later based on a correspondence relationship between the power level and the plasma state values calculated from the previously-measured plasma state values (density and temperature) and power level L0.

Specifically, for example, through a preliminary test that generates plasma, the plasma state values (density N1 and temperature T1) are measured in advance using, for example, a Langmuir probe, and a correspondence relationship between the plasma state values N1 and T1 and a power level L1 of one set of sum and difference mixed waves is specified by the analyzer 22. Further, for example, the magnitude of the first radio-frequency power is changed, a correspondence relationship between the plasma state values and a power level Ln of the mixed waves different from the power level L1 is specified, and a function (e.g., an approximate equation written using the least squares method) that shows a correspondence relationship between the power level and the plasma state values Nn and Tn is created.

The analyzer 22 inputs the subsequently measured power level Ln into the previously-created function to calculate the plasma state values Nn and Tn. Further details will be described in the simulation of the embodiment described later.

Further, using a correspondence relationship between the power level and the plasma state values calculated in this way, a change in the power level corresponding to changes in the desired plasma state values, or changes in the plasma state values corresponding to a change in the desired power level may be calculated. As described above, it is possible to adjust the plasma state values by using a correspondence relationship between the power level and the plasma state values acquired from the previously-measured power level L1 and plasma state values N1 and T1.

To achieve the adjustment of the plasma density, for example, the controller 20 or the power adjuster 23 adjusts a flow rate of the H₂ gas or Ar gas supplied from the gas supply mechanism 7, a pressure of the processing space 51, or an output of the first radio-frequency power supply 11 or the like. To achieve the adjustment of the plasma temperature, for example, the controller 20 or the power adjuster 23 adjusts the output of the first radio-frequency power supply 11 or the like. In particular, the power adjuster 23 may adjust the power to bring the power level closer to a preset target value Tt based on a correspondence relationship between the power level and the plasma state.

The adjustment of the power by the power adjuster 23 as described above may be performed manually by an operator based on the analysis results of the analyzer 22. Further, the power adjuster 23, which has acquired the analysis results of the analyzer 22, may automatically adjust the power.

### Second Embodiment

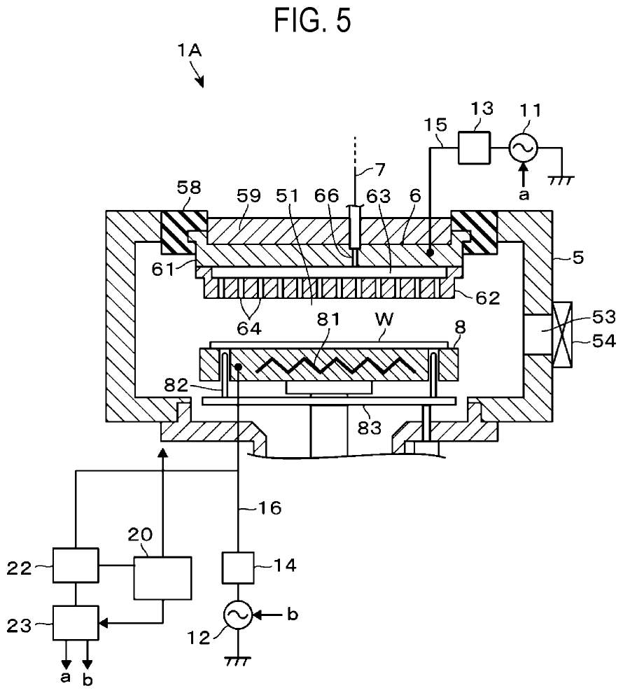

FIG. 5 is a longitudinal cross-sectional view illustrating a film forming apparatus according to a second embodiment. The film forming apparatus 1A according to the present embodiment does not have the antenna space 52, the antenna 21, and the transparent window 55. The analyzer 22 is connected to the second transmission path 16 to acquire and analyze the mixed waves propagating through the second transmission path 16. Specifically, in order to reduce the influence of the second matcher 14 or the second transmission path 16 on the mixed waves, the analyzer 22 may be connected between the second matcher 14 and the stage 8. The connection of the analyzer 22 to the transmission path is not limited to a physical connection, and a connection probe of the analyzer 22 may be brought into contact with a transmission line.

In the film forming apparatus 1A according to the present embodiment, the analyzer 22 is connected to the second transmission path 16 but is not limited thereto. For example, the analyzer 22 may be connected to any other path such as the first transmission path 15 as long as the analyzer 22 can acquire the mixed waves through a transmission path that constitutes a circuit including the first radio-frequency power supply 11, the second radio-frequency power supply 12, and the parallel flat-plate electrodes as illustrated in FIG. 2.

### Third Embodiment

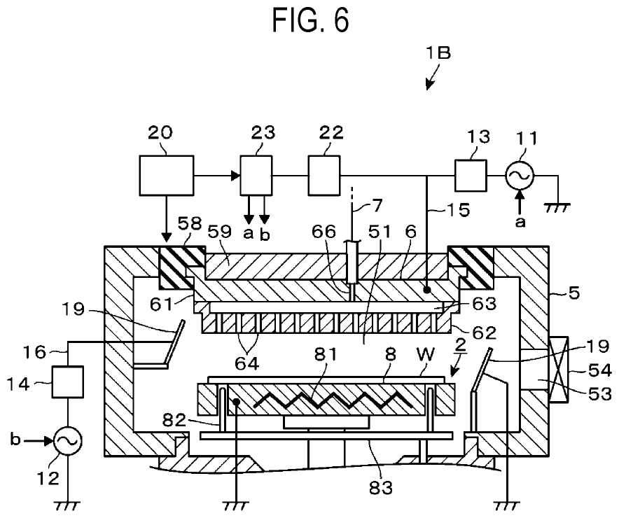

As illustrated in FIG. 6, in a film forming apparatus 1B according to this embodiment, the second radio-frequency power supply 12 is not connected to the parallel flat-plate electrodes constituted with the shower head 6 and the stage 8. Instead, a set of counter electrodes 19 are arranged in the processing space 51, and the second radio-frequency power supply 12 and the second matcher 14 are connected to one of the counter electrodes 19 via the second transmission path 16. Further, the other one of the counter electrodes 19 is grounded.

The set of counter electrodes 19 are arranged substantially to face each other to form parallel flat-plate electrodes, and a plasma space between the shower head 6 and the stage 8 is interposed between the counter electrodes 19. This allows the flow of the first radio-frequency power and the second radio-frequency power in the plasma space, resulting in the generation of mixed waves by the sheath regions Ps.

The analyzer 22 is connected to the first transmission path 15, but may be connected to the second transmission path 16 connected to the counter electrodes 19.

### Variations

In the first to third embodiments as described above, the shower head 6 and the stage 8 may take the form of substantially parallel flat-plates suitable for generating plasma by an electric field created upon the application of the first radio-frequency power. The frequencies of the first radio-frequency power and the second radio-frequency power are not limited to 1 MHz and 2 MHZ, and may be other frequencies such as, for example, those in the Industrial Scientific and Medical band (ISM band).

The first radio-frequency power supply 11 is connected to the shower head 6 but may be connected to the stage 8. The second radio-frequency power supply 12 may be connected to either the shower head 6 or the stage 8, including a case where it is connected to all connection targets of the first radio-frequency power supply 11. Regardless of a connection destination of the first radio-frequency power supply 11 and the second radio-frequency power supply 12, two frequencies of the first radio-frequency power and the second radio-frequency power pass through the sheath regions Ps to generate mixed waves.

The analyzer 22 may analyze only one of the plasma density N and the plasma temperature T. The analysis results of the plasma state by the analyzer 22 are not limited to be used for the adjustment of the power via the power adjuster 23. These analysis results may also be used only to confirm the plasma state. Further, various other methods and ranges may be set by measuring, for example, a correspondence relationship between the power level and the plasma state in advance, or calculating it using the current equation described already. For example, a plurality of power level ranges related to the ranges in which the plasma state may be identified, may be set in advance. In this case, the analyzer 22 may roughly analyze the plasma state based on which range the measured power level value falls into. Further, the control range c1 may be set to a power level range, such as Ln1 to Ln2, corresponding to a range of plasma state values set as certain film formation conditions, such as Tn1 to Tn2 or Nn1 to Nn2. In this case, the power level range is not limited to one range such as Ln1 to Ln2, but may be set to multiple divided ranges.

In the present embodiment, the analyzer 22 includes the spectrum analyzer but is not limited thereto, but may include any other measuring device as long as it may detect, for example, power levels reflecting the amplitude of current for each frequency. The provision of analyzer 22 in the film forming apparatus is not essential. For example, the measurement results of power levels may be analyzed using an external computer.

The processing of the substrate by the substrate processing apparatus according to the present disclosure is not limited to the film formation processing, but may also include other processing using plasma, such as etching and ashing. Further, the substrate W, which is a processing target, in the substrate processing apparatus of the present disclosure, is not limited to the semiconductor wafer, but may be a flat panel display (FPD) or the like.

In addition, the embodiments disclosed herein should be considered to be exemplary and not limitative in all respects. The above embodiments may be omitted, replaced, modified, or combined in various ways without departing from the scope and spirit of the appended claims.

### Examples

### Preliminary Test

An evaluation test was conducted to verify that the sum and difference mixed waves are generated with the film forming apparatus 1 according to the present disclosure.

### A. Conditions of Preliminary Test

### Example 1

Using an apparatus corresponding to the film forming apparatus 1 having the configuration described with reference to FIG. 5, first radio-frequency power of 60 MHz and 1,000 W and second radio-frequency power of 12.88 MHz and 1,000 W were applied, and electromagnetic waves were measured with a spectrum analyzer.

### Comparative Example

With the apparatus of Example 1, only first radio-frequency power of 60 MHz and 900 W was applied, and electromagnetic waves were measured using a spectrum analyzer.

### B. Results of Preliminary Test

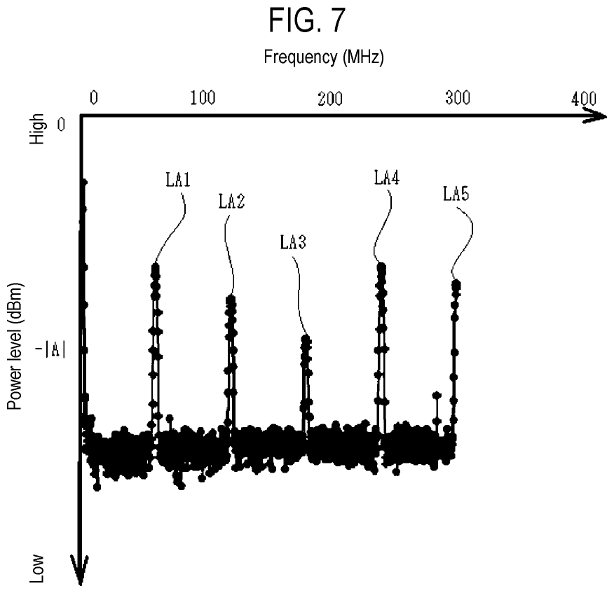

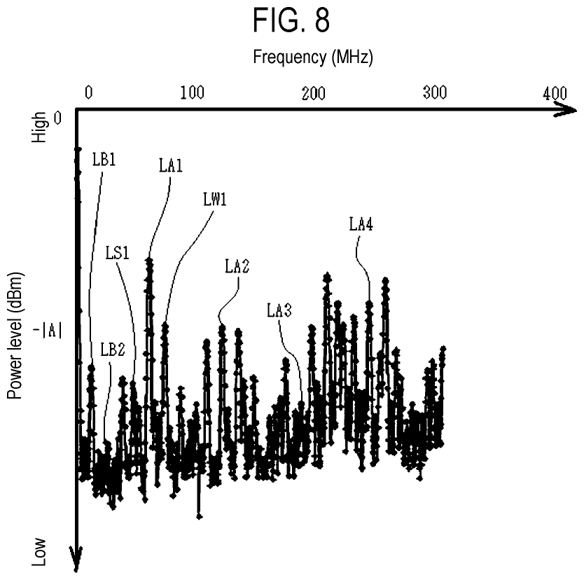

Some frequency band power levels related to the mixed waves of Example 1 and Comparative Example are illustrated in FIGS. 7 and 8. As illustrated in FIG. 7, in Example 1, multiple mixed waves were measured. Specifically, first radio-frequency power and second radio-frequency power, harmonics of the first radio-frequency power and the second radio-frequency power, and sum and difference mixed waves could be confirmed. A power level LA1 of the first radio-frequency power (60 MHZ) and power levels LA2, LA3 and LA41 of secondary to quaternary harmonics (120 MHz, 180 MHz and 240 MHZ) were measured for the power level of the first radio-frequency power. A power level LB1 of the second radio-frequency power (12.88 MHz) and a power level LB2 of secondary harmonics (25.78 MHz) were measured for the power level of the second radio-frequency power.

A power level LW1 of the sum mixed waves (72.88 MHz) and a power level LS1 of the difference mixed waves (47.12 MHz) were measured for the power levels of the sum and difference mixed waves. In this frequency band, there were many power levels of the same magnitude as the above-described power levels in addition to the above. These are likely the higher-order harmonics of the sum and difference mixed waves and tertiary or higher harmonics of the second radio-frequency power.

As illustrated in FIG. 8, in Comparative Example, the power levels LA1 to LA5 of the first radio-frequency power and harmonics of the first radio-frequency power were confirmed, and the power levels of the sum and difference mixed waves were not confirmed. As described above, it was verified that when two frequencies of the first radio-frequency power and the second radio-frequency power pass through the plasma space between the parallel flat-plate electrodes, the sum and difference mixed waves are generated, and when one frequency of only the first radio-frequency power passes through the plasma area, the sum and difference mixed waves are not generated.

### Simulation

A change in the power level of mixed waves due to a change in the plasma state of the film forming apparatus 1 according to the present disclosure was confirmed using a diode simulator. Specifically, two input waveforms corresponding to first radio-frequency power and second radio-frequency power, which are common in Examples 2 to 4, were set, and parameters in the diode current equation described already corresponding to the plasma temperature and density, which are different in Examples 2 to 4, were set, respectively. The simulator was used to simulate the power levels of the mixed waves in each of Examples 2 to 4 using the diode current equation.

### A. Experimental Conditions

### Example 2

The two input waveforms were set such that one contained 20 cycles in 1024 data and the other contained 2 cycles in 1024 data, and were also set such that the frequency of one was 10 times the frequency of the other. Further, the two input waveforms were set to have the same amplitude, i.e., the same power amplitude. As for plasma state values, the plasma temperature was set to 25 degrees C. (298 K), and the reverse saturation current Ir as a plasma density parameter was set to 1×10⁻¹⁹ (A).

### Example 3

Under the same conditions as in Example 2, only the plasma temperature was changed to 125 degrees C. (398 K).

### Example 4

Under the same conditions as in Example 3, only the reverse saturation current Ir was set to 1×10⁻¹⁸ (A).

### B. Results of Simulation

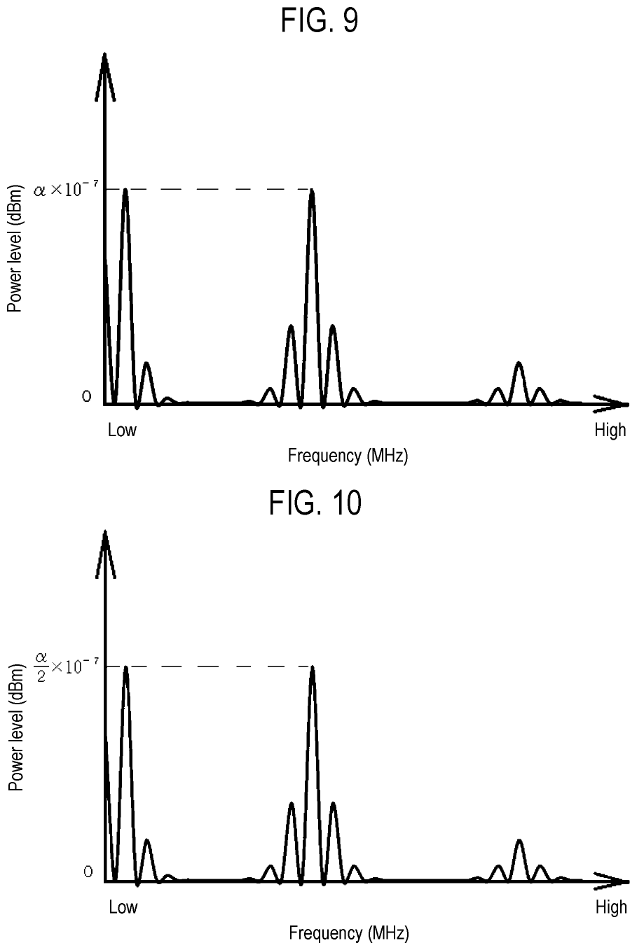

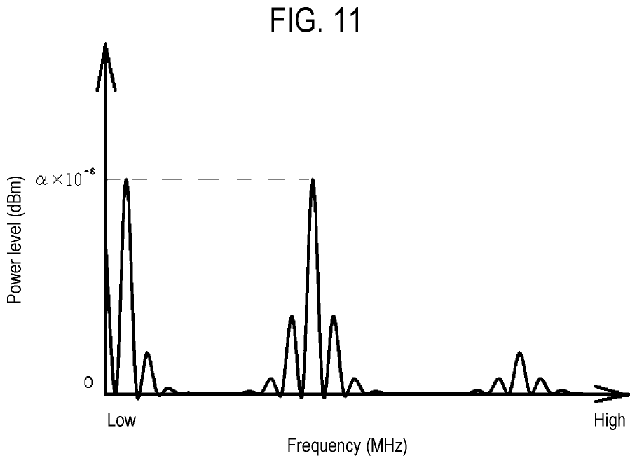

FIGS. 9 to 11 illustrate the simulation results indicating the power levels of the sum and difference mixed waves in Examples 2 to 4. In these drawings, the power levels of the sum and difference mixed waves are on the basis of the same frequency for comparison. As illustrated in FIG. 9, in Example 2, the power level was α×10⁻⁷(dBm). Here, α is a positive integer. As illustrated in FIG. 10, in Example 3, the power level was α/2×10⁻⁷(dBm). As illustrated in FIG. 11, in Example 4, the power level was α×10⁻⁶(dBm). In this way, it was found that the power level changes with a change in the plasma temperature among the plasma state values.

From the above results, for example, the diode simulator may be used to calculate the power levels matching the first and second radio-frequency powers as well as the plasma temperature and density, which are preset based on the film forming operation. Specifically, the two input waveforms, diode temperature, and reverse saturation current Ir are set in the diode simulator to match the first and second radio-frequency powers and the plasma temperature and density, which are preset based on the film forming operation. This allows the simulator to calculate a target power level. Further, in the same way, target values of the plasma temperature and density may be set, the two waveforms may be simulated with various settings, and the first radio-frequency power or power level for approaching the target values of the plasma temperature and density may be calculated. As described above, the correspondence relationship between the power level and the plasma state values, which are acquired in advance, is not limited to actual measurements as described above, but may also be appropriately acquired using a simulator or other methods, and the plasma state values and the first radio-frequency power may be controlled using various approaches.

According to the present disclosure in some embodiments, it is possible to analyze a state of plasma from mixed waves of radio-frequency powers.

While certain embodiments have been described, these embodiments have been presented by way of example only, and are not intended to limit the scope of the disclosures. Indeed, the embodiments described herein may be embodied in a variety of other forms. Furthermore, various omissions, substitutions and changes in the form of the embodiments described herein may be made without departing from the spirit of the disclosures. The accompanying claims and their equivalents are intended to cover such forms or modifications as would fall within the scope and spirit of the disclosures.

What is claimed is:

1. A substrate processing apparatus comprising:
a processing container having a processing space in which a substrate is processed;
a gas supply mechanism configured to supply a reaction gas to the processing space;
a metal-made shower head arranged in the processing space and connected to the gas supply mechanism, the metal-made shower head being configured to discharge the reaction gas supplied from the gas supply mechanism into the processing space;
a metal-made stage arranged to face the metal-made shower head in the processing space, the metal-made stage being configured to place the substrate on the metal-made stage, and the metal-made stage and the metal-made shower head being configured to constitute parallel flat-plate electrodes;
a first radio-frequency power supply connected to either the metal-made shower head or the metal-made stage and configured to supply first radio-frequency power to generate a plasma of the reaction gas between the parallel flat-plate electrodes;
a second radio-frequency power supply configured to supply second radio-frequency power to the plasma, the second radio-frequency power having a frequency different from a frequency of the first radio-frequency power; and
an analyzer configured to acquire a mixed wave of the first radio-frequency power and the second radio-frequency power, which is obtained by the generation of the plasma, and to analyze a state of the plasma based on a result obtained by measuring a power level of the mixed wave.

2. The substrate processing apparatus of claim 1, wherein the state of the plasma is at least one of a temperature of the plasma and a density of the plasma.

3. The substrate processing apparatus of claim 1, further comprising: a power adjuster configured to adjust power supplied to the first radio-frequency power supply according to the state of the plasma analyzed from the power level.

4. The substrate processing apparatus of claim 3, wherein the power adjuster adjusts the power so as to bring the power level closer to a preset target value based on a correspondence relationship between the power level and the state of the plasma, which are acquired in advance.

5. The substrate processing apparatus of claim 1, further comprising:
an antenna space provided to be adjacent to the processing space;
a transparent window arranged between the antenna space and the processing space to transmit an electromagnetic wave emitted from the plasma through the transparent window; and
an antenna arranged in the antenna space,
wherein the analyzer acquires the mixed wave via the antenna.

6. The substrate processing apparatus of claim 1, wherein the analyzer acquires the mixed wave via a transmission path that constitutes a circuit including the first radio-frequency power supply, the second radio-frequency power supply, and the parallel flat-plate electrodes.

7. The substrate processing apparatus of claim 1, wherein the second radio-frequency power supply is connected to either the metal-made shower head or the metal-made stage.

8. The substrate processing apparatus of claim 1, further comprising: a set of counter electrodes arranged across a space in which the plasma is generated between the parallel flat-plate electrodes,
wherein the second radio-frequency power supply is connected to one of the counter electrodes.

9. The substrate processing apparatus of claim 1, wherein the analyzer analyzes the state of the plasma based on a power level of a first mixed wave corresponding to a sum of the frequency of the first radio-frequency power and the frequency of the second radio-frequency power or a difference between the frequency of the first radio-frequency power and the frequency of the second radio-frequency power, or harmonics of the frequency of the first radio-frequency power and the frequency of the second radio-frequency power, the first mixed wave and the harmonics being included in the mixed wave.

10. A plasma measurement method performed by a substrate processing apparatus, the plasma measurement method comprising:
discharging, by a metal-made shower head which is arranged in a processing space of a processing container and is connected to a gas supply mechanism, a reaction gas supplied from the gas supply mechanism to the processing space in which a substrate is processed;
supplying first radio-frequency power from a first radio-frequency power supply to generate a plasma of the reaction gas between parallel flat-plate electrodes, and supplying second radio-frequency power from a second radio-frequency power supply to the generated plasma, wherein the first radio-frequency power supply is connected to either the metal-made shower head or a metal-made stage which places the substrate thereon, the metal-made stage is arranged to face the metal-made shower head in the processing space, the metal-made shower head and the metal-made stage constitute the parallel flat-plate electrodes, and the second radio-frequency power has a frequency different from a frequency of the first radio-frequency power; and
acquiring a mixed wave of the first radio-frequency power and the second radio-frequency power, which is obtained by the generation of the plasma, and analyzing a state of the plasma based on a result obtained by measuring a power level of the mixed wave.

11. The plasma measurement method of claim 10, wherein the state of the plasma is at least one of a temperature of the plasma and a density of the plasma.

12. A substrate plasma regulation method comprising:
adjusting, by a power adjuster, power supplied to the first radio-frequency power supply based on the state of the plasma analyzed in the analyzing the state of the plasma according to claim 11.

13. The substrate plasma regulation method of claim 12, wherein the power adjuster adjusts the power so as to bring the power level closer to a preset target value based on a correspondence relationship between the power level and the state of the plasma, which are acquired in advance.
